(19) United States
(12) Patent Application Publication
(10) Pub. No.: US 2012/0146028 A1
(43) Pub. Date: Jun. 14, 2012

(54) PHOTOSENSOR, SEMICONDUCTOR DEVICE, AND LIQUID CRYSTAL PANEL

(75) Inventors: Akihiro Oda, Osaka-shi (JP); Seiji Kaneko, Osaka-shi (JP)

(73) Assignee: SHARP KABUSHIKI KAISHA, Osaka-shi (JP)

(21) Appl. No.: 13/391,211

(22) PCT Filed: Jul. 26, 2010
(86) PCT No.: PCT/JP2010/062552

§ 371 Date: Feb. 17, 2012

(30) Foreign Application Priority Data
Aug. 20, 2009 (JP) 2009-190982

(51) Int. Cl. H01L 29/786

(52) U.S. Cl. 257/53; 257/57; 257/72; 257/E29.273

(57) ABSTRACT

The light use efficiency of a thin film diode is improved even when the semiconductor layer of the diode has a small thickness, thereby improving the light detection sensitivity of the diode. Further, a short circuit between the electrodes of the thin film diode via the light-blocking layer is prevented. A thin film diode (130) having a first semiconductor layer (131) including, at least, an n-type region (131n) and a p-type region (131p) is provided on one side of a substrate (101), and a light-blocking layer (160) is provided between the substrate and the first semiconductor layer. A metal oxide layer (180) is provided on the side of the light-blocking layer facing the first semiconductor layer. Asperities are provided on the side of the metal oxide layer facing the first semiconductor layer, and the first semiconductor layer has a geometry of asperities conforming with the asperities on the metal oxide layer.

### REFERENCE TO RELATED APPLICATIONS

This application is the national stage under 35 USC 371 of International Application No. PCT/JP2010/062552, filed Jul. 26, 2010, which claims priority of Japanese Patent Application No. 2009-190982, filed Aug. 20, 2009, the entire contents of which are incorporated herein by reference.

### FIELD OF THE INVENTION

The present invention relates to a photosensor that includes a thin film diode (TFD) having a semiconductor layer including, at least, an n-type region and a p-type region. Further, the present invention relates to a semiconductor device including a thin film diode and a thin film transistor (TFT). Furthermore, the present invention relates to a liquid crystal panel including such a semiconductor device.

### BACKGROUND OF THE INVENTION

Touch sensor functionality can be established by incorporating a photosensor including a thin film diode into a display device. In such a display device, information can be input as a finger or a touch pen touches the viewer's side (i.e. the display surface) of the display device and the resulting change in light entering the display surface is detected by a photosensor.

In such a display device, a change in light resulting from a finger touching the display surface may be small depending on the environment, such as the ambient brightness. As such, a change in light may not be detected by a photosensor.

JP2008-287061A discloses a technique for improving the light detection sensitivity of a photosensor in a semiconductor device used in a liquid crystal display device. The technique will now be described referring to FIG. 7.

This semiconductor device includes, on a substrate (active matrix substrate) 910, insulating layers 941, 942, 943 and 944 formed in this order, a thin film diode 920 and a thin film transistor 930. The thin film diode 920 is a PIN diode having a semiconductor layer 921 composed of an n-type region 921n, a p-type region 921p and a low resistance region 921i. The p-type region 921p and the n-type region 921n are connected with electrodes 923a and 923b, respectively, both electrodes penetrating the insulating layers 943 and 944. The thin film transistor 930 includes a semiconductor layer 931 composed of a channel region 931c, an n-type region 931a as the source region, and an n-type region 931b as the drain region. A gate electrode 932 is provided above the channel region 931c with an insulating layer 943 interposed therebetween. The source region 931a and the drain region 931b are connected with electrodes 933a and 933b, respectively, both electrodes penetrating the insulating layers 943 and 944. The drain region 931b is connected with a pixel electrode (not shown) via the electrode 933b.

The thin film diode 920 receives light entering the display surface (the top of paper in FIG. 7). A light-blocking layer 990 is provided between the thin film diode 920 and the substrate 910 to prevent light from the backlight (not shown) on the side of the substrate 910 opposite the display surface (the bottom of paper in FIG. 7) from entering the thin film diode 920. The light-blocking layer 990 extends along the surface of a recess 992, which is formed by removing a portion of the insulating layer 941. The recess 992 is tapered, becoming wider toward the top, to form a slope 991 of the light-blocking layer 990 extending along the slope of the recess 992.

The light-blocking layer 990 also serves as a reflective layer. Accordingly, light traveling through the display surface that did not enter the thin film diode 920 but entered the area between the thin film diode 920 and the light-blocking layer 990 is reflected from the light-blocking layer 990 and enters the thin film diode 920. The slope 991 of the light-blocking layer 990 reflects light incident on the slope 991 back to the thin film diode 920.

In the semiconductor device shown in FIG. 7, the light-blocking layer 990 described above causes more light that entered the display surface to enter the thin film diode 920. Thus, light detection sensitivity is improved.

### SUMMARY OF THE INVENTION

However, the semiconductor device shown in FIG. 7 has the following problems.

Firstly, the thin film diode 920 does not provide sufficient light detection sensitivity. The reasons will be discussed below.

The semiconductor layer 921 of the thin film diode 920 is formed at the same time as the semiconductor layer 931 of the thin film transistor 930. Thus, the semiconductor layer 921 has a very small thickness. Consequently, part of light that entered the semiconductor layer 921 is not absorbed by the semiconductor layer 921 and passes through. As such, even though light entering the area between the thin film diode 920 and the light-blocking layer 990 is reflected from the slope 991 back toward the semiconductor layer 921, part of light reflected toward the semiconductor layer 921 may not be absorbed by the semiconductor layer 921 and may pass through the semiconductor layer 921. Moreover, the slope 991 is only provided near the edge of the light-blocking layer 990. Thus, most of the light reflected from the slope 991 enters the periphery of the thin film diode 920. As a result, only a small amount of light enters the low resistance region 921i, which constitutes the light receiving region.

Secondly, the electrodes 923a and 923b of the thin film diode 920 may be short circuited. The reasons are as follows.

Typically, the electrodes 923a and 923b are formed by forming contact holes in the insulating layers 944 and 943 and then depositing a metal material in these contact holes. The contact holes are formed by conducting dry etching (for example, reactive ion etching (RIE)) to form holes from the surface of the insulating layer 944 down to the insulating layer 943, and then conducting wet etching (for example, buffer hydrogen fluoride (BHF)). Wet etching is conducted last because silicon dioxide, which constitutes the insulating layer 943, can be etched using dry etching or wet etching, whereas silicon, which constitutes the semiconductor layer 921, can be etched using dry etching but can be hardly etched using wet etching. However, controlling etching depth in dry etching may be difficult such that a dry etching step may result in holes that penetrate the semiconductor layer 921. In this case, the subsequent wet etching step etches the insulating layer 942, resulting in contact holes that reach the light-blocking layer 990. Thereafter, a metal material is deposited in the contact holes, which leads to a short circuit between the electrodes 923a and 923b via the light-blocking layer 990, as shown in FIG. 8.

An object of the present invention is to solve such problems with the conventional art by improving light use efficiency and thus improving the light detection sensitivity of the thin film diode even when the semiconductor layer of the thin film diode has a small thickness. Another object of the present invention is to prevent a short circuit between the two electrodes of a thin film diode via a light-blocking layer.

The photosensor of the present invention includes: a substrate; a thin film diode provided close to one side of the substrate and having a first semiconductor layer including, at least, an n-type region and a p-type region; and a light-blocking layer provided between the substrate and the first semiconductor layer. A metal oxide layer is formed on a side of the light-blocking layer facing the first semiconductor layer. Asperities are formed on a side of the metal oxide layer facing the first semiconductor layer. The first semiconductor layer has a geometry of asperities conforming with the asperities of the metal oxide layer.

According to the present invention, asperities are formed on the metal oxide layer. Thus, light incident on the metal oxide layer is diffusely reflected from the asperities on the metal oxide layer and enters the first semiconductor layer. The first semiconductor layer has a geometry of asperities conforming with the asperities on the metal oxide layer. Thus, light that has been diffusely reflected travels a longer distance inside the first semiconductor layer. As a result, a larger amount of light is absorbed in the first semiconductor layer. Accordingly, light use efficiency is improved even when the first semiconductor layer has a small thickness, thereby improving light detection sensitivity.

The metal oxide layer is provided facing the first semiconductor layer. Thus, the metal oxide layer serves as an etching stop when etching is conducted to form contact holes through which electrodes of a thin film diode are to be formed. As a result, contact holes are prevented from extending down to the light-blocking layer. Further, the metal oxide layer is insulating. Therefore, even if contact holes are formed that reach the metal oxide layer and the resulting electrodes are in contact with the metal oxide layer, the electrodes are not short circuited via the metal oxide layer.

### BRIEF DESCRIPTION OF THE DRAWINGS

FIG. 1 is a schematic cross sectional view of a semiconductor device according to Embodiment 1 of the present invention.

FIG. 2 is an enlarged cross sectional view of section II of FIG. 1 for explaining how the light detection sensitivity of the thin film diode is improved in the semiconductor device according to Embodiment 1 of the present invention.

FIG. 3A is a cross sectional view of the semiconductor device according to Embodiment 1 of the present invention, illustrating one manufacturing step thereof.

FIG. 3B is a cross sectional view of the semiconductor device according to Embodiment 1 of the present invention, illustrating one manufacturing step thereof.

FIG. 3C is a cross sectional view of the semiconductor device according to Embodiment 1 of the present invention, illustrating one manufacturing step thereof.

FIG. 3D is a cross sectional view of the semiconductor device according to Embodiment 1 of the present invention, illustrating one manufacturing step thereof.

FIG. 3E is a cross sectional view of the semiconductor device according to Embodiment 1 of the present invention, illustrating one manufacturing step thereof.

FIG. 3F is a cross sectional view of the semiconductor device according to Embodiment 1 of the present invention, illustrating one manufacturing step thereof.

FIG. 3G is a cross sectional view of the semiconductor device according to Embodiment 1 of the present invention, illustrating one manufacturing step thereof.

FIG. 3H is a cross sectional view of the semiconductor device according to Embodiment 1 of the present invention, illustrating one manufacturing step thereof.

FIG. 3I is a cross sectional view of the semiconductor device according to Embodiment 1 of the present invention, illustrating one manufacturing step thereof.

FIG. 3J is a cross sectional view of the semiconductor device according to Embodiment 1 of the present invention, illustrating one manufacturing step thereof.

FIG. 4 is a schematic cross sectional view of a liquid crystal display device including a liquid crystal panel according to Embodiment 2 of the present invention.

FIG. 5 is an equivalent circuit of one pixel of the liquid crystal panel according to Embodiment 2 of the present invention.

FIG. 6 is a perspective view of major parts of another liquid crystal display device according to Embodiment 2 of the present invention.

FIG. 7 is a cross sectional view of a conventional semiconductor device including a thin film diode and a thin film transistor.

FIG. 8 is a cross sectional view of a conventional semiconductor device including a thin film diode and a thin film transistor for explaining how the two electrodes of the thin film diode are short circuited.

### DETAILED DESCRIPTION OF THE INVENTION

A photosensor according to an embodiment of the present invention includes: a substrate; a thin film diode provided close to one side of the substrate and having a first semiconductor layer including, at least, an n-type region and a p-type region; and a light-blocking layer provided between the substrate and the first semiconductor layer, wherein a metal oxide layer is formed on a side of the light-blocking layer facing the first semiconductor layer; asperities are formed on a side of the metal oxide layer facing the first semiconductor layer; and the first semiconductor layer has a geometry of asperities conforming with the asperities of the metal oxide layer (first arrangement).

In the first arrangement, asperities are formed on the side of the metal oxide layer facing the first semiconductor layer. Thus, light incident on the side of the metal oxide layer facing the first semiconductor layer may be diffusely reflected. Preferably, the asperities are irregular and random ones. Since light can be reflected in different directions, the incident angle dependence of light detection sensitivity of the thin film diode may be reduced.

The first semiconductor layer has a geometry of asperities conforming with the asperities formed on the metal oxide layer. It may be easily determined whether the first semiconductor layer has a geometry of asperities conforming with the asperities on the metal oxide layer by observing a cross section of the layer in the thickness direction using SEM (hereinafter referred to as “cross section SEM observation”), for example. That the first semiconductor layer has a geometry of asperities conforming with the asperities on the metal oxide layer means that, in a cross section SEM observation, for example, the first semiconductor layer is displaced upward at a position where the side of the metal oxide layer facing the first semiconductor layer forms an upward apex, and the first semiconductor layer is displaced downward at a position where it forms a downward concave. As a result, the lower side (i.e. the side facing the metal oxide layer) and the upper side (i.e. the side opposite the side thereof facing the metal oxide layer) of the first semiconductor layer with a substantially uniform thickness has asperities conforming with the asperities formed on the side of the metal oxide layer facing the first semiconductor layer.

Since the first semiconductor layer has a geometry of asperities conforming with the asperities on the metal oxide layer, light diffusely reflected from the metal oxide layer may travel a longer distance inside the first semiconductor layer.

In the first arrangement, it is preferable that the first semiconductor layer has a thickness smaller than a difference in height between an apex and a bottom of the asperities formed on a side of the first semiconductor layer facing the metal oxide layer (second arrangement). Preferably, the thickness of the first semiconductor layer is smaller than the difference in height between an apex and a bottom of the asperities formed on the side of the metal oxide layer facing the first semiconductor layer. As the first semiconductor layer has such a small thickness, the first semiconductor layer may be formed in the same process as the second semiconductor layer constituting a thin film transistor. As a result, the manufacturing process may be made simpler. The thickness of the first semiconductor layer and the difference in height between an apex and a bottom of asperities on the first semiconductor layer and the metal oxide layer may be measured in a cross section SEM observation. The lower limit of thickness of the first semiconductor layer is not limited to a particular value; however, it is preferably equal to or larger than, for example, a half of the difference in height in the asperities formed on the side of the first semiconductor layer facing the metal oxide layer and the difference in height in the asperities formed on the side of the metal oxide layer facing the first semiconductor layer. If the intended thickness of the first semiconductor layer is too small, it is difficult to form a continuous film that is to be a thin first semiconductor layer without pin holes.

In the first or second arrangement, it is preferable that a difference in height between an apex and a bottom of the asperities formed on the side of the metal oxide layer facing the first semiconductor layer is in a range of 50 to 100 nanometers (third arrangement). If the difference in height in the asperities on the metal oxide layer is smaller than this range of number, light incident on the metal oxide layer may not be diffusely reflected; further, if the difference in height in the asperities on the metal oxide layer is smaller than this range of number, the asperities on the upper and lower sides of the first semiconductor layer are relatively small and the first semiconductor layer is almost flat; thus, light reflected from the metal oxide layer travels a short distance in the first semiconductor layer; as a result, it is difficult to improve light detection sensitivity. If, on the other hand, the difference in height in the asperities on the metal oxide layer is larger than that range of number, it is difficult to form a continuous film that is to be a thin first semiconductor layer without pinholes.

In any one of the first to third arrangements, it is preferable that the asperities are formed on an entire surface of the side of the metal oxide layer facing the first semiconductor layer (fourth arrangement). Thus, light incident on the metal oxide layer is diffusely reflected irrespective of the incident position. As a result, the light detection sensitivity of the photosensor (thin film diode) is further improved. In addition, the process of forming asperities may be made simpler than in an implementation where asperities are formed in a limited area.

In any one of the first to fourth arrangements, an interlayer insulating film covering the first semiconductor layer and a pair of electrodes penetrating the interlayer insulating film and electrically connected with the n-type region and the p-type region may further be included. In this case, at least one of the electrodes may reach the metal oxide layer (fifth arrangement). Thus, in the photosensor according to an embodiment of the present invention, contact holes for electrodes may extend deep down such that the resulting electrodes reach the metal oxide layer. As a result, the etching depth for forming contact holes does not have to be precisely controlled.

A semiconductor device according to an embodiment of the present invention includes: the photosensor according to an embodiment of the present invention as described above; and a thin film transistor provided close to the same side of the substrate as the thin film diode, wherein the thin film transistor includes: a second semiconductor layer including a channel region, a source region and a drain region; a gate electrode that controls a conductivity of the channel region; and a gate insulating film provided between the second semiconductor layer and the gate electrode (sixth arrangement). Since a thin film diode and a thin film transistor are provided on a common substrate, the semiconductor device according to an embodiment of the present invention can be employed in various applications where light detection functionality is required.

In the sixth arrangement, it is preferable that the first semiconductor layer and the second semiconductor layer are formed on a single insulating layer (seventh arrangement). Thus, the first and second semiconductor layers may be formed concurrently in a single process. As a result, the manufacturing process may be simplified.

In the sixth or seventh arrangement above, it is preferable that a side of the second semiconductor layer facing the substrate is flat (eight arrangement). Thus, the light detection sensitivity of the thin film diode may be improved without adversely affecting the gate capability or the like of the thin film transistor. The side of the second semiconductor layer facing the substrate does not have to be completely flat but, suitably, it is substantially flat.

In any one of the sixth to eighth arrangements, it is preferable that the first semiconductor layer has a thickness that is identical with that of the second semiconductor layer (ninth arrangement). Thus, the first and second semiconductor layers may be formed concurrently in a single process. As a result, the manufacturing process may be simplified. The first semiconductor layer and the second semiconductor layer do not have to be completely identical in thickness but, suitably, they are substantially identical.

A liquid crystal panel according to an embodiment of the present invention includes: the semiconductor device above; a counter substrate facing the side of the substrate where the thin film diode and the thin film transistor are provided; and a liquid crystal layer enclosed between the substrate and the counter substrate (tenth arrangement). Thus, a liquid crystal panel with touch sensor functionality or ambient sensor functionality for measuring the ambient brightness may be realized.

Now, the present invention will be described in detail based on several preferred embodiments. Of course, the present invention is not limited to the embodiments below. For purposes of explanation, the drawings referred to in the following description only show, in a simplified form, those components of the embodiments of the present invention that are relevant to the description of the present invention. Accordingly, the present invention may include any desired component(s) not shown in the drawings. Further, the sizes of the components in the drawings do not exactly reflect the sizes of the actual components and the size ratios of the components.

### Embodiment 1

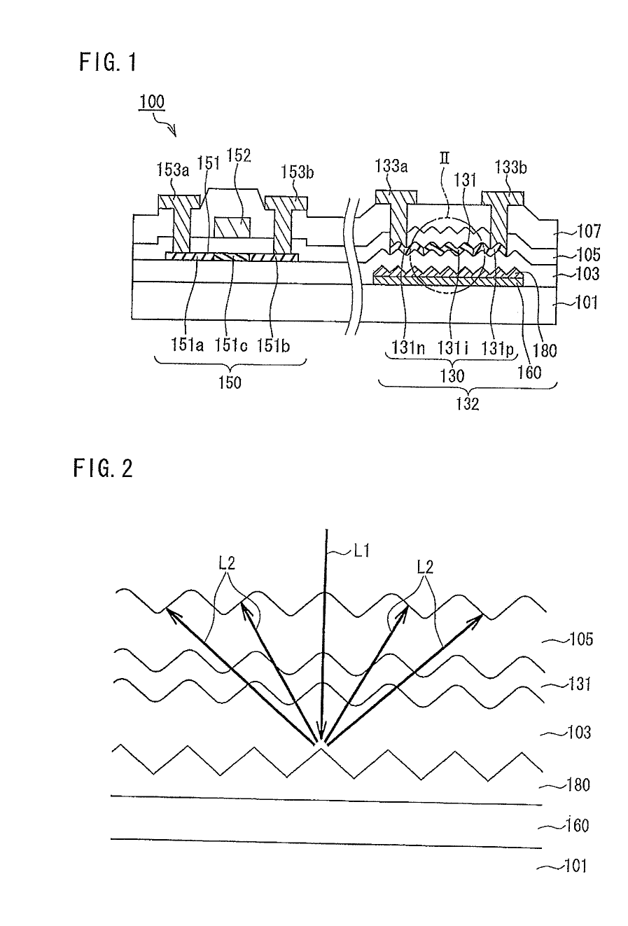

FIG. 1 is a schematic cross sectional view of a semiconductor device 100 according to Embodiment 1 of the present invention. The semiconductor device 100 includes: a photosensor 132 having a substrate 101, a thin film diode 130 formed above the substrate 101 with interposed base layer 103 therebetween as an insulating layer, and a light-blocking layer 160 provided between the substrate 101 and the thin film diode 130; and a thin film transistor 150. The substrate 101 is preferably translucent. To simplify the drawing, FIG. 1 only shows a single photosensor 132 and a single thin film transistor 150; however, a plurality of photosensors 132 and a plurality of thin film transistors 150 may be formed on a common substrate 101. Further, to facilitate understanding, FIG. 1 shows a cross section of the photosensor 132 and that of the thin film transistor 150 in the same drawing; however, these cross sections do not have to be on a single common plane.

The thin film diode 130 has a semiconductor layer (first semiconductor layer) 131 including, at least, an n-type region 131n and a p-type region 131p. In the present embodiment, an intrinsic region 131i is provided between the n-type region 131n and the p-type region 131p in the semiconductor layer 131. Electrodes 133a and 133b are connected with the n-type region 131n and the p-type region 131p, respectively.

The thin film transistor 150 includes: a semiconductor layer (second semiconductor layer) 151 including a channel region 151c, a source region 151a and a drain region 151b; a gate electrode 152 for controlling the conductivity of the channel region 151c; and a gate insulating film 105 provided between the semiconductor layer 151 and the gate electrode 152. Electrodes 153a and 153b are connected with the source region 151a and the drain region 151b, respectively. The gate insulating film 105 expands over the semiconductor layer 131, too.

The semiconductor layer 131 of the thin film diode 130 and the semiconductor layer 151 of the thin film transistor 150 may have different crystallinities or the same crystallinity. If the two layers have the same crystallinity, the crystal conditions of the semiconductor layers 131 and 151 do not have to be controlled separately. As a result, a reliable and high-performance semiconductor device 100 can be provided without complicating the manufacturing process.

An interlayer insulating film 107 is formed on the thin film diode 130 and the thin film transistor 150.

A light-blocking layer 160 is provided between the substrate 101 and thin film diode 130 facing the thin film diode 130. This prevents light that entered the side of the substrate 101 opposite that with the thin film diode 130 and passed the substrate 101 from entering the semiconductor layer 131. More particularly, the light-blocking layer 160 is located on the substrate 101 in a position that includes an area facing the semiconductor layer 131.

A metal oxide layer 180 is provided on the side of the light-blocking layer 160 facing the semiconductor layer 131. Small and random asperities are provided on the side of the metal oxide layer 180 facing the thin film diode 130 (upper surface). The semiconductor layer 131 of the thin film diode 130 has a geometry of asperities conforming with the asperities on the metal oxide layer 180. More specifically, the first semiconductor layer 131 having a substantially uniform thickness in a cross section taken in the thickness direction as shown in FIG. 1 is displaced upward and downward (i.e. is bent) with a substantially constant distance between itself and the asperities on the upper surface of the metal oxide layer 180.

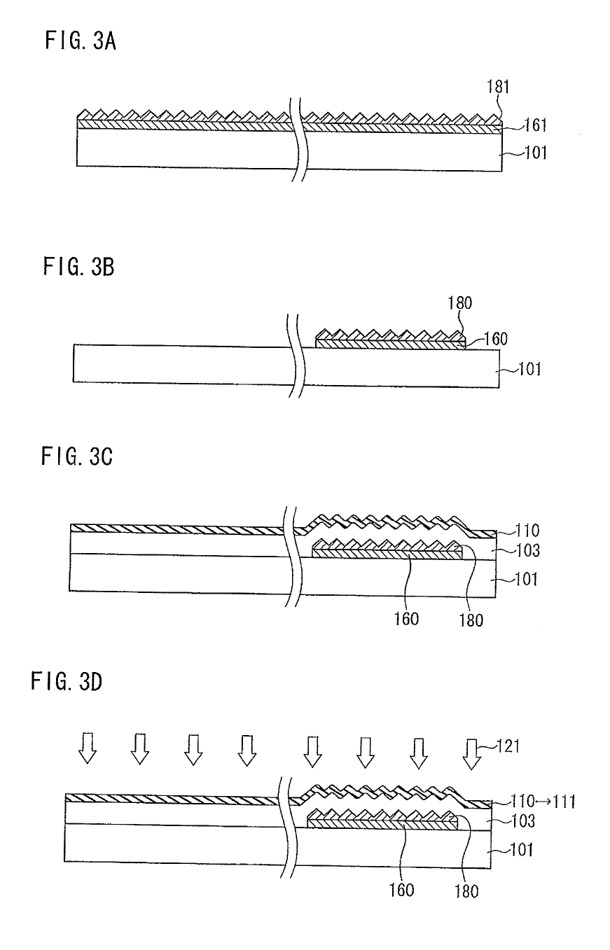

Effects of the asperities on the upper surface of the metal oxide layer 180 and the geometry of asperities of the semiconductor layer 131 constituting the thin film diode 130 will now be described. FIG. 2 is an enlarged cross sectional view of section II of FIG. 1 including the light-blocking layer 160, the metal oxide layer 180 and the semiconductor layer 131. Incident light, L1, traveling toward the thin film diode 130 from above enters the semiconductor layer 131 of the thin film diode 130 and is, ideally, absorbed by the semiconductor layer 131. However, since the semiconductor layer 131 has a small thickness, a portion of the incident light L1 passes through the semiconductor layer 131. The portion of the incident light L1 that has passed through the semiconductor layer 131 passes through the base layer 103 and reaches the upper surface of the metal oxide layer 180. The incident light L1 cannot pass through the metal oxide layer 180. Random asperities are provided on the upper surface of the metal oxide layer 180. Thus, the metal oxide layer 180 diffusely reflects the incident light L1. The reflected light, L2, which has been diffusely reflected from the upper surface of the metal oxide layer 180, travels in different directions, passes through the base layer 103 and enters the semiconductor layer 131. Those reflected light L2 beams that were reflected in relatively large reflection angles generally enter the semiconductor layer 131 in large incident angles. As a result, light reflected in a relatively large reflection angle tends to travel a long distance inside the semiconductor layer 131. In addition, the semiconductor layer 131 substantially conforms with the asperities on the metal oxide layer 180. Thus, even those incident light L1 and reflected light L2 beams that form relatively small angles with respect to the normal line of the substrate 101 tend to travel a longer distance inside the semiconductor layer 131 than in an implementation where the semiconductor layer 131 is flat. Thus, according to the present invention, the incident light L1 and the reflected light L2 travel a longer distance inside the semiconductor layer 131. Consequently, more light is absorbed in the semiconductor layer 131. As a result, light use efficiency is improved and thus the light detection sensitivity of the thin film diode 130 is improved. Further, the more random the asperities on the upper surface of the metal oxide layer 180 and the geometry of the semiconductor layer 131 are, the smaller incident angle dependence and thus the more stable improvement in light detection sensitivity can be achieved.

Preferably, the random asperities on the upper surface of the metal oxide layer 180 cover the entire upper surface of the metal oxide layer 180. Thus, the light detection sensitivity of the thin film diode 130 is improved irrespective of the incident location of the incident light L1 on the metal oxide layer 180. Further, since the area where asperities are formed is not limited, the step of forming asperities is simplified.

Suitably, the semiconductor layer 131 of the thin film diode 130 has a geometry of asperities conforming with the asperities on the upper surface of the metal oxide layer 180 in at least the intrinsic region 131i; however, it is preferable that this applies to the entire area including the n-type region 131n and the p-type region 131p. The manufacturing process is thus simplified.

The present invention improves light detection sensitivity even if the semiconductor layer 131 is so thin that most of the incident light L1 passes through the semiconductor layer 131. For example, even if the semiconductor layer 131 has a thickness that is smaller than the difference in height between the apexes and bottoms of the asperities on the lower surface of the semiconductor layer 131, the reflected light L2 travels a longer distance inside the semiconductor layer 131, as shown in FIG. 2. As a result, the light detection sensitivity of the thin film diode 130 is improved. Accordingly, it is not necessary to increase the thickness of the semiconductor layer 131 to reduce the amount of light passing through the semiconductor layer 131. As a result, the semiconductor layer 131 may be formed in the same process as the semiconductor layer 151 of the thin film transistor 150, as will be discussed below.

One example of a method of manufacturing such a semiconductor device 100 according to the present embodiment will be described. However, methods of manufacturing a semiconductor device 100 are not limited to the example below.

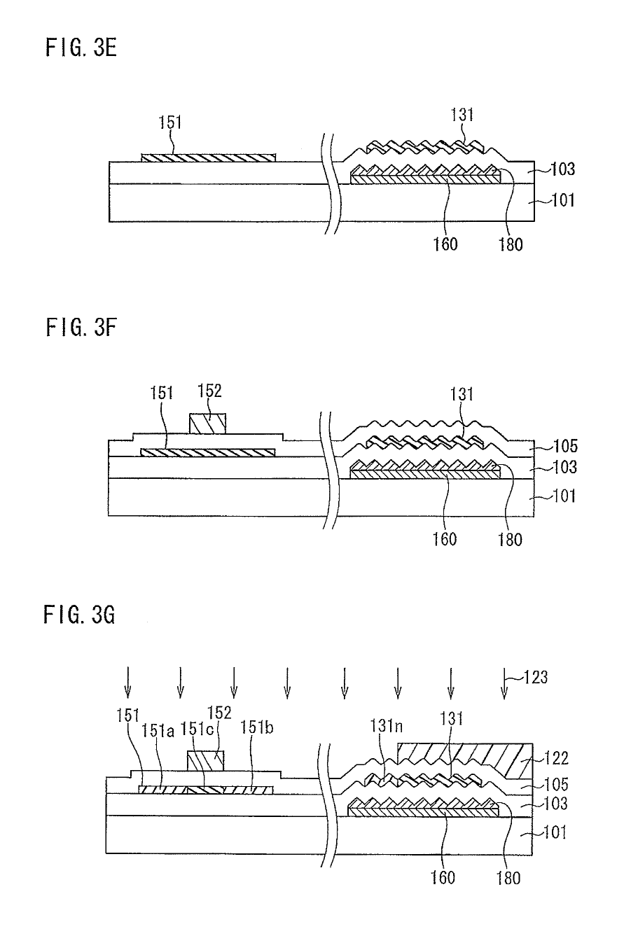

First, as shown in FIG. 3A, a first thin film 161 that is to be a light-blocking layer 160 later and a second thin film 181 that is to be a metal oxide layer 180 are formed in this order on a substrate 101.

The substrate 101 is not limited to a particular type and can be selected as appropriate according to the application of the semiconductor device 100 or other conditions; however, a translucent glass substrate (such as a low-alkali glass substrate) or quartz substrate may be used, for example. If the substrate 101 is a low-alkali glass substrate, the substrate 101 may be thermally treated in advance at a temperature about 10 to 20° C. lower than the glass strain point.

The first thin film 161 may be made of a metal material, for example. Particularly, high-melting-point metals such as tantalum (Ta), tungsten (W) and molybdenum (Mo) are preferable when thermal treatments in later manufacturing steps are taken into consideration. A film of such a metal material is formed over the substrate 101 using sputtering. The thickness of the first film 161 is preferably in the range of about 100 to 200 nanometers.

The second film 181 is made of a metal oxide, and preferably has a high electric resistance. The second film may be formed, for example, using sputtering in an oxide atmosphere, where tantalum (Ta), tungsten (W), molybdenum (Mo) or the like listed above that forms the first film 161 serves as a target. The second film 181 is preferably made of tantalum oxide (Ta₂O₅). The second film 181 is formed over the entire surface of the substrate 101. The thickness of the second film 181 is preferably in the range of about 50 to 200 nanometers. As sputtering is used, columnar crystals of the metal material extending in the thickness direction (i.e. the vertical direction on paper in FIG. 3A) are formed in the formed second film 181. As a result, random asperities are formed on the surface of the second film 181. Further, anisotropic etching, such as reactive ion etching, may be performed on the surface of the second film 181 in the thickness direction. The etching depth is preferably in the range of about 20 to 100 nanometers. Since columnar crystals are formed in the second film 181, the surface of the second film 181 is selectively etched, such that the asperities on the surface of the second film 181 becomes larger. The degree of asperities on the surface of the second film 181, i.e. the difference in height between an apex and a bottom of the asperities (i.e. the distance in the thickness direction), is preferably in the range of about 50 to 100 nanometers.

Next, a pattern of a desired light-blocking layer 160 is formed on the upper surface of the second film 181 using a resist. Then, unnecessary portions of the first film 161 and the second film 181 are removed using wet etching. The portions of the first film 161 and the second film 181 where a thin film diode 130 is to be formed later are left out. The portions of the first film 161 and the second film 181 outside the area for the thin film diode 130, including the area(s) where a thin film transistor 150 is to be formed later, are removed. As a result, a patterned light-blocking layer 160 and metal oxide layer 180 are provided, as shown in FIG. 3B.

Next, as shown in FIG. 3C, a base layer 103 is formed to cover the substrate 101, the light-blocking layer 160 and the metal oxide layer 180, before an amorphous semiconductor film 110 is formed.

The base layer 103 is provided to prevent impurities from diffusing from the substrate 101. The base layer 103 may be made of, for example, a simple layer made of silicon oxide, a multiple layer made of a silicon nitride film and a silicon oxide film in this order from the substrate 101, or other known compositions. Such a base layer 103 may be formed using plasma CVD, for example. The thickness of the base layer 103 is preferably in the range of 100 to 600 nanometers, more preferably in the range of 150 to 450 nanometers.

Preferable semiconductors that may constitute the amorphous semiconductor film 110 include silicon; however, other semiconductors such as Ge, SiGe, compound semiconductors, or chalcogenide may also be used. The following description uses silicon. The amorphous silicon film 110 is formed using a known technique, such as plasma CVD or sputtering. Preferably, the thickness of the amorphous silicon film 110 is in the range of 25 to 100 nanometers, which allows high-quality polycrystalline silicon to be obtained during the following crystallization process by laser illumination. For example, an amorphous silicon film 110 with a thickness of 50 nanometers may be formed using plasma CVD. If the base layer 103 and the amorphous silicon film 110 are formed using the same film-formation method, these two layers may be formed consecutively. Surface contamination of the base layer 103 is prevented, as the base layer 103 is not exposed to the atmosphere after it is formed. As a result, variations in properties or variations in threshold voltage of the fabricated thin film transistor 150 and the thin film diode 130 are reduced.

As shown in FIG. 3C, in the area where the metal oxide layer 180 was formed, asperities conforming with the asperities on the upper surface of the metal oxide layer 180 are formed on the upper surface of the base layer 103 and the upper surface of the amorphous silicon film 110.

Next, as shown in FIG. 3D, the amorphous silicon film 110 is crystallized by illuminating the amorphous silicon film 110 with a laser beam 121 from above. The laser beam 121 may be an XeCl excimer laser beam (with a wavelength of 308 nanometers and a pulse width of 10 to 150 nanoseconds, for example 40 nanoseconds) or a KrF excimer laser beam (with a wavelength of 248 nanometers and a pulse width of 10 to 150 nanoseconds). The laser beam 121 is adjusted to illuminate an area of an elongated shape on the surface of the substrate 101. The entire surface of the amorphous silicon film 110 is crystallized by scanning it with the laser beam 121 sequentially in a direction perpendicular to the elongation of the area of the surface of the substrate 101 illuminated by the laser 121. Preferably, scanning with the laser beam 121 is performed such that some portions of two consecutive illuminated areas lie over each other at a given moment. Thus, any given point on the amorphous silicon film 110 is illuminated with a laser multiple times. As a result, the homogeneity of crystal conditions of the polycrystalline silicon film 111 is improved. When illuminated with the laser beam 121, the amorphous silicon film 110 melts for a moment and then solidifies, during which process the film is crystallized to become a polycrystalline silicon film 111.

Next, as shown in FIG. 3E, the unnecessary portions of the polycrystalline silicon film 111 are removed to separate the devices from each other. The devices may be separated from each other using photolithography, that is, by removing the unnecessary portions of the polycrystalline silicon film 111 using dry etching after a resist of a predetermined pattern is formed. Thus, the semiconductor layer 131 which is to be an active region (i.e. an n³⁰ -type region, a p⁺-type region and an intrinsic region) of a thin film diode 130 later and the semiconductor layer 151 which is to be an active region (i.e. a source region, a drain region and a channel region) of a thin film transistor 150 later are formed separate from each other. Thus, these semiconductor layers 131 and 151 are formed like islands.

Next, as shown in FIG. 3F, after a gate insulating film 105 covering these island-like semiconductor layers 131 and 151 are formed, a gate electrode 152 of the thin film transistor 150 is formed on the gate insulating film 105.

Preferably, the gate insulating film 105 is a silicon oxide film. The thickness of the gate insulating film 105 is preferably in the range of 20 to 150 nanometers (for example, 100 nanometers). As shown in FIG. 3F, in the area where the metal oxide layer 180 was formed, asperities conforming with the asperities on the upper surface of the metal oxide layer 180 are formed on the upper surface of the gate insulating film 105.

The gate electrode 152 is formed by depositing a conductive film over the gate insulating film 105 using sputtering or CVD and patterning this conductive film. It is desirable that the conductive film be made of a high-melting-point metal such as W, Ta, Ti, Mo or an alloy thereof. Further, the thickness of the conductive film is preferably in the range of 300 to 600 nanometers.

Next, as shown in FIG. 3G, a mask 122 made of a resist is formed on the gate insulating film 105, covering an area including the portion of the semiconductor layer 131 that is to be an active region of the thin film diode 130 later. Then, the entire surface of the substrate 101 is ion-doped with n-type impurities (such as phosphorus) 123 from above the substrate 101. The n-type impurities 123 pass through the gate insulating film 105 and are injected into the semiconductor layers 151 and 131. This step injects n-type impurities 123 into the regions of the semiconductor layer 131 of the thin film diode 130 not covered with the mask 122 and the regions of the semiconductor layer 151 of the thin film transistor 150 not covered with the gate electrode 152. The regions covered with the mask 122 or the gate electrode 152 are not doped with n-type impurities 123. Thus, the region of the semiconductor layer 131 of the thin film diode 130 into which n-type impurities 123 are injected is to be the n-type region 131n of the thin film diode 130 later. The regions of the semiconductor layer 151 of the thin film transistor 150 into which n-type impurities 123 are injected are to become the source region 151a and the drain region 151b of the thin film transistor later. The region of the semiconductor layer 151 that is masked with the gate electrode 152 and into which no n-type impurities 123 are injected is to become the channel region 151c of the thin film transistor 150 later.

Next, after the mask 122 is removed, as shown in FIG. 3H, a mask 124 made of a resist is formed on the gate insulating film 105, covering an area including the portion of the semiconductor layer 131 that is to be an active region of the thin film diode 130 later, and the entire semiconductor layer 151, which is to be an active region of the thin film transistor 150 later. Then, the entire surface of the substrate 101 is ion-doped with p-type impurities (such as boron) 125 from above the substrate 101. The p-type impurities 125 pass through the gate insulating film 105 and are injected into the semiconductor layer 131. This step injects p-type impurities 125 into the region of the semiconductor layer 131 of the thin film diode 130 not covered with the mask 124. The regions covered with the mask 124 are not doped with p-type impurities 125. Thus, the region of the semiconductor layer 131 of the thin film diode 130 into which p-type impurities 125 are injected is to become the p-type region 131p of the thin film diode 130 later. Further, the regions of the semiconductor layer 131 into which no p-type impurities and no n-type impurities are injected are to become the intrinsic region 131i later.

Next, as shown in FIG. 3I, after the mask 124 is removed, thermal treatment is performed in an inert atmosphere, such as a nitrogen atmosphere. This thermal treatment removes doping damage, such as crystal deficiencies produced during doping, in the n-type region 131n and the p-type region 131p of the thin film diode 130, as well as in the source region 151a and the drain region 151b of the thin film transistor 150, and phosphorus and boron injected therein are activated. This thermal treatment may be performed using a typical heating furnace; however, it is preferably performed using RTA (rapid thermal annealing). Methods in which hot inert gases are blown onto the surface of the substrate 101 and temperature is rapidly increased and decreased are particularly suitable.

Next, as shown in FIG. 3J, an interlayer insulating film 107 is formed. The interlayer insulating film 107 is not limited to a particular structure, and any known compositions may be used. For example, a double structure in which a silicon nitride film and a silicon oxide film are formed in this order may be used. Thermal treatment for hydrogenating the semiconductor layers 151 and 131, such as annealing at 350 to 450° C. in a nitrogen atmosphere or hydrogen mixture atmosphere at 1 atmosphere, for example, may be performed where necessary.

Thereafter, contact holes are formed in the interlayer insulating film 107. Next, a film made of a metal material (for example, a double film of titanium nitride and aluminum) is formed on the interlayer insulating film 107 and inside the contact holes, and this film is patterned. Thus, the electrodes 133a and 133b of the thin film diode 130 and the electrodes 153a and 153b of the thin film transistor 150 are formed.

Methods of forming contact holes are not limited to a particular one, and the following conventional method may be used, for example.

First, a pattern of contact holes are formed, using a resist, on the surface of the interlayer insulating film 107. Next, holes are formed, using dry etching (for example, reactive ion etching), to reach the gate insulating film 105. Finally, wet etching is conducted using BHF or the like to form contact holes that reach the semiconductor layer 131.

As discussed above, controlling etching depth in dry etching is generally difficult, such that a dry etching step may result in holes penetrating the semiconductor layer 131. In this case, the wet etching step after the dry etching etches the base layer 103. However, the metal oxide layer 180 is present under the base layer 103 and serves as an etching stop that prevents further etching.

Thereafter, a film made of a metal material that is to form the electrodes 133a and 133b is formed inside the contact holes. If the contact holes reach the metal oxide layer 180, the metal material is in contact with the metal oxide layer 180. However, the metal oxide layer 180 is insulating such that the electrodes 133a and 133b are not short circuited.

As described above, a metal oxide layer 180 may be provided on the side of the light-blocking layer 160 facing the semiconductor layer 131 to solve the problem with the conventional art of the electrodes 133a and 133b being short circuited. Further, the need to precisely managing etching depth for forming contact holes is eliminated.

According to the present invention, the metal oxide layer 180 serves as an etching stop. As a result, the wet etching step may be omitted if contact holes that extend down to at least the semiconductor layer 131 are formed using dry etching only, for example.

However, dry etching may damage the semiconductor layer 131, resulting in an increased contact resistance with electrodes. Accordingly, it is preferable if dry etching is conducted up to the proximity of the semiconductor layer 131 (for example, around the middle of the gate insulating film 105) and then wet etching is used, thereby minimizing the increase in contact resistance and providing good ohmic characteristics.

By forming the electrodes 133a, 133b, 153a and 153b in this manner, a thin film diode 130 connected with the electrodes 133a and 133b and a thin film transistor 150 connected with the electrodes 153a and 153b are provided, as shown in FIG. 3J. A protection film made of, for example, a silicon nitride film (not shown) may be provided on the interlayer insulating film 107 in order to protect the electrodes 133a and 133b connected with the thin film diode 130 and the electrodes 153a and 153b connected with the thin film transistor 150.

According to the above method, the semiconductor layer 131 of the thin film diode 130 and the semiconductor layer 151 of the thin film transistor 150 may be formed concurrently. As a result, a thin film diode 130 and a thin film transistor 150 may be fabricated efficiently on a common substrate 101.

This manufacturing method necessarily produces a semiconductor layer 131 of a thin film diode 130 with a thickness equal to that of the semiconductor layer 151 of the thin film transistor 150. As such, the thickness of the semiconductor layer 131 of the thin film diode 130 cannot be increased to improve light detection sensitivity. However, as discussed above, in a semiconductor device 100 according to an embodiment of the present invention, the light detection sensitivity of the thin film diode 130 is improved even if the thickness of the semiconductor layer 131 cannot be increased.

Further, according to the above manufacturing method, forming asperities on the upper surface of the metal oxide layer 180 causes the semiconductor layer 131 of the thin film diode 130 deposited thereafter to be in a geometry of asperities conforming with the asperities on the upper surface of the metal oxide layer 180.

Thus, according to the above manufacturing method, a semiconductor device may be fabricated in a simple manner and at low cost without significantly altering the conventional manufacturing process of semiconductor devices.

As shown in FIG. 3B, the portions of the first film 161 and the second film 181 where a thin film transistor 150 is to be formed are removed. Thus, the upper and lower surfaces of the semiconductor layer 151 constituting the thin film transistor 150 are substantially flat. Thus, the light detection sensitivity of the thin film diode 130 is improved without adversely affecting properties (for example, decreasing the gate capability) of the thin film transistor 150.

The thin film transistor is not limited to the structure described above. For example, a dual-gate thin film transistor, an LDD or GOLD thin film transistor, a p-channel thin film transistor or the like may be used. Moreover, several types of thin film transistors with different structures may be combined.

The above embodiment has illustrated a semiconductor device 100 including a photosensor 132 and a thin film transistor 150. However, the present invention is not limited thereto. For example, only a photosensor 132 may be made. Further, the semiconductor layers 131 and 151 may be formed of amorphous silicon.

### Embodiment 2

Embodiment 2 illustrates a liquid crystal panel including a semiconductor device having light detection functionality illustrated in Embodiment 1.

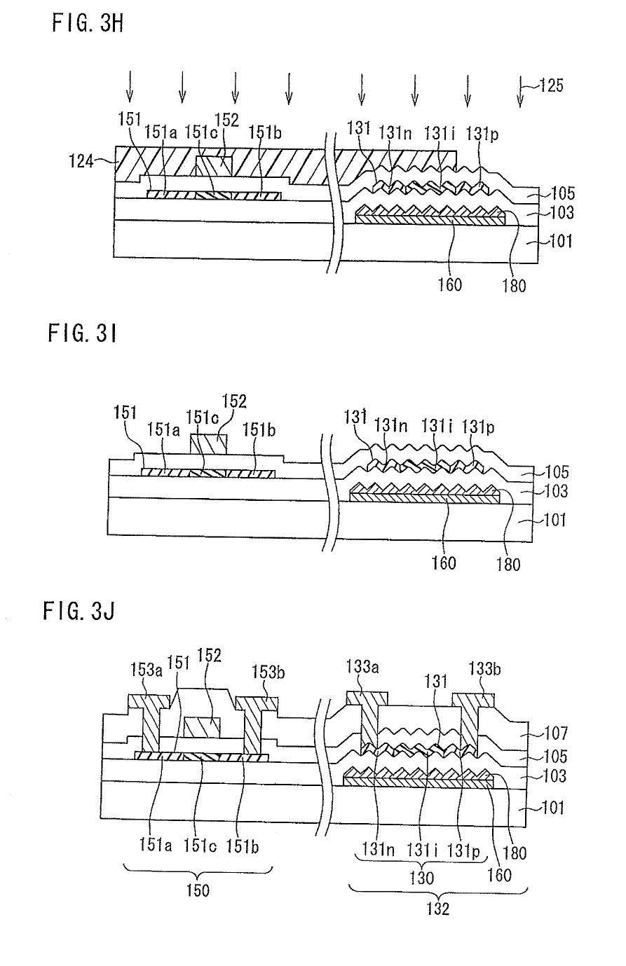

FIG. 4 is a schematic cross sectional view of a liquid crystal display device 500 including a liquid crystal panel 501 according to Embodiment 2.

The liquid crystal display device 500 includes a liquid crystal panel 501, an illuminating device 502 that illuminates the backside of the liquid crystal panel 501, and a translucent protection panel 504 disposed above the liquid crystal panel 501 with an air gap 503 interposed therebetween.

The liquid crystal panel 501 includes a TFT array substrate 510 and a counter substrate 520, both of which are translucent plates, and a liquid crystal layer 519 enclosed between the TFT array substrate 510 and the counter substrate 520. The TFT array substrate 510 and the counter substrate 520 are not limited to any particular material. The same materials that are used in conventional liquid crystal panels, such as glass or an acrylic resin, may be used.

A polarizer 511 that passes or absorbs specific polarization components is provided on the side of the TFT array substrate 510 facing the illuminating device 502. An insulating layer 512 and an oriented film 513 are deposited in this order on the side of the TFT array substrate 510 opposite the polarizer 511. The oriented film 513 is a layer in which liquid crystals are oriented, and is formed of an organic film such as polyimide. Inside the insulating layer 512 are formed: a pixel electrode 515 composed of a transparent and conductive film, such as ITO; a thin film transistor (TFT) 550 connected with the pixel electrode 515 for working as a switching device for driving liquid crystal; and a thin film diode 530 having light detection functionality. A light-blocking layer 560 is formed on the side of the thin film diode 530 facing the illuminating device 502.

A polarizer 521 that passes or absorbs specific polarization components is provided on the side of the counter substrate 520 opposite the liquid crystal layer 519. On the side of the counter substrate 520 facing the liquid crystal layer 519 are formed, starting from the liquid crystal layer 519, an oriented film 523, a common electrode 524 and a color filter 525 in this order. Similar to the oriented film 513 on the TFT array substrate 510, the oriented film 523 is a layer in which liquid crystals are oriented and is formed of an organic film, such as polyimide. The common electrode 524 is made of a transparent and conductive film, such as ITO. The color filter layer 525 includes three types of resin films (color filters) that each selectively pass light in the wavelength range of one of the primary colors: red (R), green (G) and blue (B), and a black matrix as a light-blocking layer disposed between two adjacent color filters. Preferably, no color filter or black matrix is provided in the region corresponding to a thin film diode 530.

In the liquid crystal panel 501 of the present embodiment, one pixel electrode 515 and one thin film transistor 550 are disposed for a color filter of one of the primary colors: red, green and blue, and all these together form a pixel of a primary color (subpixel). Three subpixels of red, green and blue form a color pixel (pixel). Such color pixels are arranged regularly in the vertical and horizontal directions.

The translucent protection panel 504 is made of a flat plate of glass or an acrylic resin, for example. The side of the translucent protection panel 504 opposite the liquid crystal panel 501 is a touch sensor side 504a that can be touched by a human finger 509. Disposing a translucent protection panel 504 above the liquid crystal panel 501 with an air gap 503 interposed therebetween prevents a depressing force by the human finger 509 onto the translucent protection panel 504 from being transmitted to the liquid crystal panel 501. This prevents an undesired waving pattern from being generated on the display screen by the depressing force by the finer 509.

The illuminating device 502 is not limited to a particular type and any illuminating device known as an illuminating device for a liquid crystal panel may be used. For example, a direct-lighting or edge-light illuminating device may be used. An edge-light illuminating device is preferable since it is advantageous in realizing a thin liquid crystal display device. The light source is not limited to a particular type, either, and a cold/hot-cathode tube or an LED may be used, for example.

The liquid crystal display device 500 of the present embodiment is capable of displaying a color image by permitting light from the illuminating device 502 to pass through the liquid crystal panel 501 and the translucent protection panel 504.

Meanwhile, external light, L, that entered the touch sensor side 504a enters the thin film diode 530. When the finger 509 touches the touch sensor side 504a, part of the external light L is blocked. As a change in the external light L entering a thin film diode 530 is detected, it can be determined whether the finger 509 is in contact with the touch sensor side 504a and where it is in contact with it. The light-blocking layer 560 prevents light from the illuminating device 502 from entering the thin film diode 530.

In the above arrangement, the thin film diode 530, the thin film transistor 550, the light-blocking layer 560 and the TFT array substrate 510 may be the thin film diode 130, the thin film transistor 150, the light-blocking layer 160 and the substrate 101 illustrated in Embodiment 1. The insulating layer 512 includes the base layer 103, the gate insulating film 105, the interlayer insulating film 107 and the planarizing film, illustrated in Embodiment 1.

FIG. 4 shows a transmissive liquid crystal display device as the liquid crystal display device; however, the present invention is not limited thereto and may be used in a semi-transmissive or reflective liquid crystal display device. No illuminating device 502 is required in a reflective liquid crystal display device.

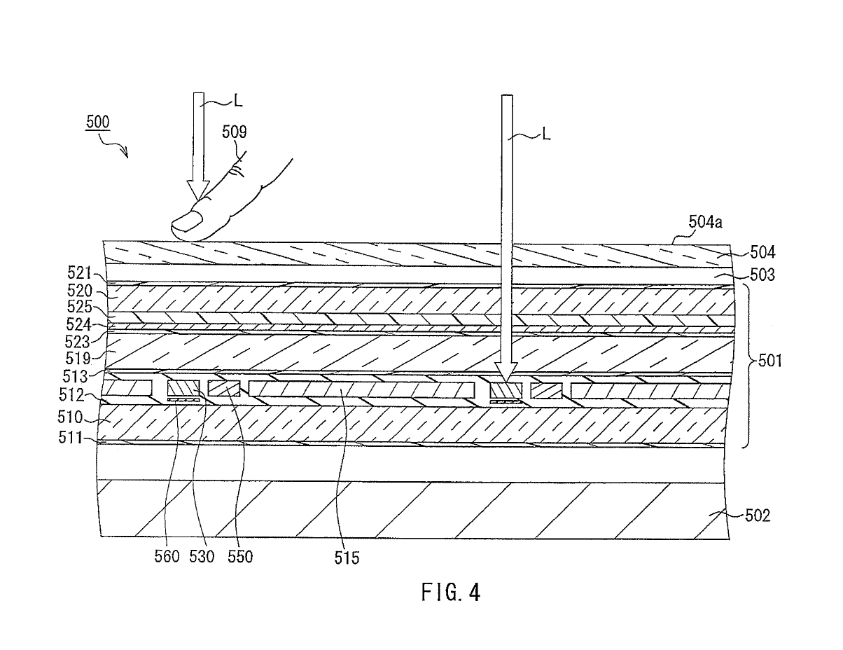

FIG. 5 is an equivalent circuit of one pixel of the liquid crystal panel 501 shown in FIG. 4. The pixel 570 of the liquid crystal panel 501 includes a display section 570a, constituting a color pixel, and a photosensor section 570b. A large number of such pixels 570 are arranged in a matrix in the horizontal and vertical directions in the pixel region of the liquid crystal panel 501.

The display section 570a includes thin film transistors 550R, 550G and 550B, liquid crystal elements 551R, 551G and 551B, and electrostatic capacitances 552R, 552G and 552B (the suffixes R, G and B indicate that the elements correspond to the red, green and blue subpixels constituting a pixel. The same applies to the following description). The source regions of the thin film transistors 550R, 550G and 550B are connected with the source electrode lines (signal lines) SLR, SLG and SLB, respectively. The gate electrodes are connected with the gate electrode line (scan line) GL. Each of the drain regions is connected with the pixel electrode of the respective one of the liquid crystal elements 551R, 551G and 551B (see the pixel electrode 515 of FIG. 4) and one of the electrodes of the respective one of the electrostatic capacitances 552R, 552G and 552B. The other one of the electrodes of each of the electrostatic capacitances 552R, 552G and 552B is connected with the common electrode line TCOM.

When a positive pulse is applied to the gate electrode line GL, the thin film transistors 550R, 550G and 550B are turned on. Thus, a signal voltage applied to the source electrode lines SLR, SLG and SLB is transmitted from the source electrodes of the thin film transistors 550R, 550G and 550B, respectively, via the respective drain electrodes to the liquid crystal elements 551R, 551G and 551B, respectively, and the electrostatic capacitances 552R, 552G and 552B, respectively. As a result, a voltage is applied to the liquid crystal layer 519 (see FIG. 4) by means of the pixel electrodes 515 of the liquid crystal elements 551R, 551G and 551B (see FIG. 4) and the common electrode 524 (see FIG. 4) to change the orientation of liquid crystal molecules in the liquid crystal layer 519 to achieve a desired color display.

The photosensor section 570b includes a thin film diode 530, a storage capacitance 531, and a thin film transistor 532. The p⁺-type region of the thin film diode 530 is connected with the reset signal line RST. The n⁺-type region of the thin film diode 530 is connected with one electrode of the storage capacitance 531 and the gate electrode of the thin film transistor 532. The other electrode of the storage capacitance 531 is connected with the read-out signal line RWS. The drain electrode of the thin film transistor 532 is connected with the source electrode line SLG. The source electrode of the thin film transistor 532 is connected with the source electrode line SLB. The source electrode line SLG is connected with a rated voltage VDD. The source electrode line SLB is connected with the drain electrode of a bias transistor 533. The source electrode of the bias transistor 533 is connected with a rated voltage VSS.

In the photosensor section 570b of this configuration, an output voltage VPIX corresponding to the amount of light received by the thin film diode 530 is obtained in the following manner.

First, a high-level reset signal is supplied to the reset signal line RST. Thus, the thin film diode 530 is forward biased. At this point, the potential of the gate electrode of the thin film transistor 532 is lower than the threshold voltage of the thin film transistor 532, such that the thin film transistor 532 is non-conductive.

Next, the potential of the reset signal line RST is lowered to low level. Thus, an integration period of photocurrent begins. During this integration period, the amount of photocurrent proportional to the amount of light entering the thin film diode 530 flows out of the storage capacitance 531, discharging the storage capacitance 530. Even during the integration period, the potential of the gate electrode of the thin film transistor 532 is lower than the threshold voltage of the thin film transistor 532, such that the thin film transistor 532 remains non-conductive.

Next, a high-level read-out signal is supplied to the read-out signal line RWS. Thus, the integration period ends and a read-out period begins. As a read-out signal is supplied, electric charge is injected into the storage capacitance 531, such that the potential of the gate electrode of the thin film transistor 532 becomes higher than the threshold voltage of the thin film transistor 532. As a result, the thin film transistor 532 becomes conductive and works together with the bias transistor 533 to function as a source follower amplifier. The output voltage VPIX obtained from the thin film transistor 532 is proportional to the value of integral of photocurrent of the thin film diode 530 during the integration period.

Next, the potential of the read-out signal line RWS is lowered to low level and the read-out period ends.

These operations are repeated for each of the pixels 570 arranged in the pixel region of the liquid crystal panel 501 to provide touch sensor functionality in the pixel region of the liquid crystal panel 501.

Using the thin film diode 130 illustrated in Embodiment 1 as the thin film diode 530 will realize a liquid crystal display device 500 having touch sensor functionality with excellent light detection sensitivity.

In FIG. 5, one photosensor section 570b is provided for one display section 570a constituting a color pixel; however, the present invention is not limited to such an arrangement. For example, one photosensor section 570b may be provided for a plurality of display sections 570a. Alternatively, one photosensor section 570b may be provided for each of the subpixels for red, blue and green within one display section 570a. Further, while FIG. 5 shows an implementation where the present invention is employed in a liquid crystal panel for color display, the present invention may also be employed in a liquid crystal panel for monochrome display.

FIGS. 4 and 5 illustrate an implementation where the thin film transistor 150 of Embodiment 1 is the thin film transistor 550 (550R, 550G and 550B) provided in each of the subpixels; however, the present invention is not limited thereto. The thin film transistor 150 may be a thin film transistor shown in FIG. 5 other than the thin film transistors 550 (550R, 550G and 550B) provided in the subpixels. Alternatively, the thin film transistor 150 may be a thin film transistor for a driver circuit (the gate driver 510g or the source driver 510s described below), for example.

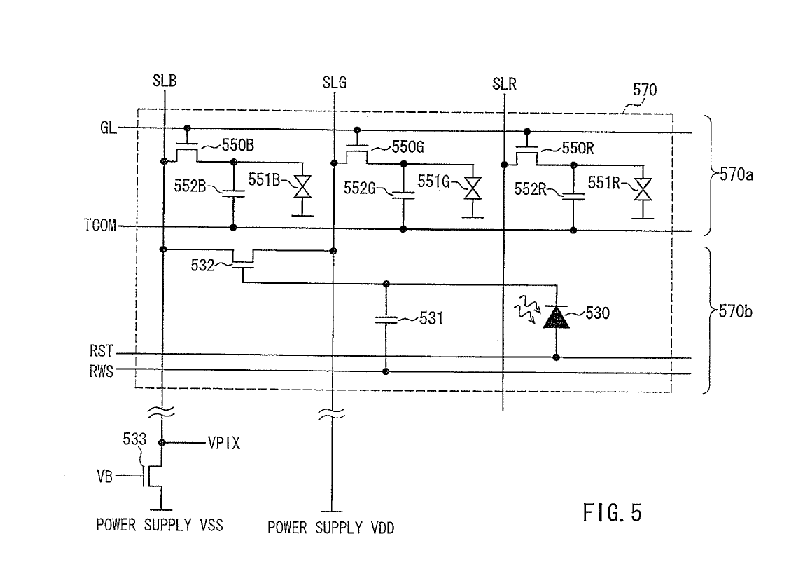

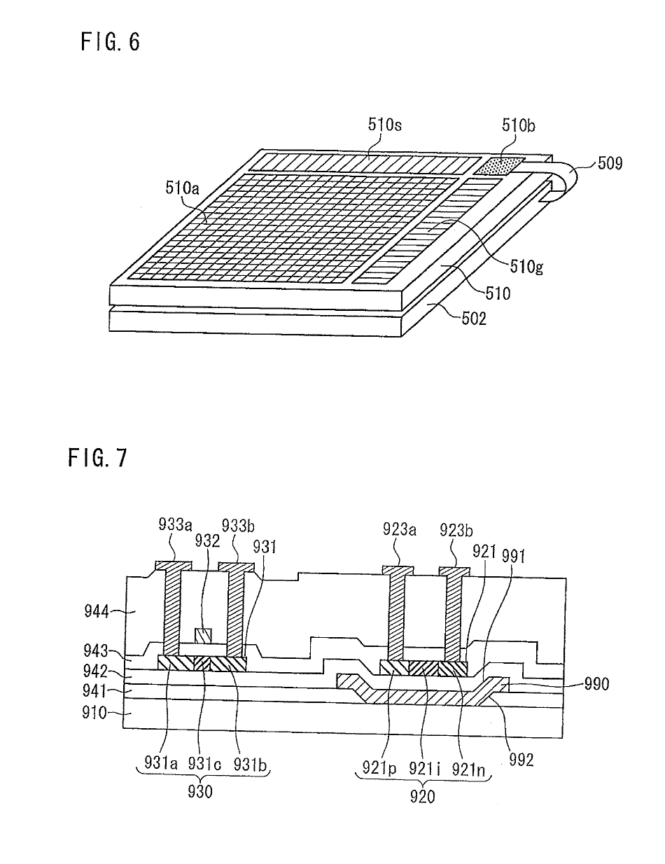

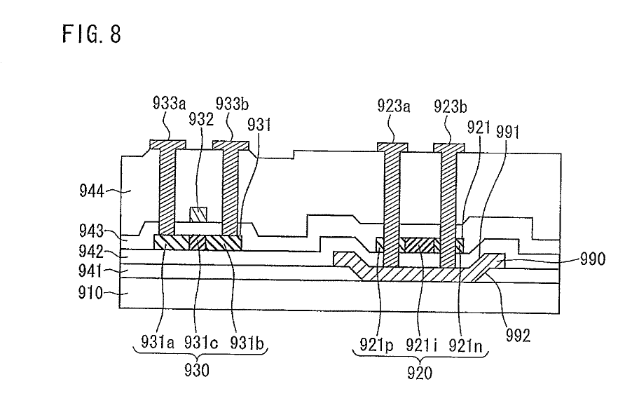

In FIGS. 4 and 5, the photosensor of the present invention having light detection functionality is provided in the pixel region of a TFT array substrate 510, in which a large number of thin film transistors 550 for driving liquid crystal are disposed in a matrix. However, the present invention is not limited to such an arrangement. For example, the photosensor may be provided outside the pixel region of the TFT array substrate 510. An example of this will be described referring to FIG. 6.

Out of the components of a liquid crystal display device, FIG. 6 only shows the TFT array substrate 510 and the illuminating device 502 that illuminates the backside of the TFT array substrate 510. The TFT array substrate 510 includes a pixel region 510a in which a large number of thin film transistors for driving liquid crystal are arranged in a matrix, and a gate driver 510g, a source driver 510s and a light detection unit 510b are provided in a frame-shaped area around the pixel region 510a. The photosensor 132 illustrated in Embodiment 1 (the thin film diode 130, the light-blocking layer 160 and the metal oxide layer 180) is formed in the light detection unit 510b. The thin film diode 130 in the light detection unit 510b generates an illuminance signal corresponding to the brightness of the environment. The illuminance signal is input to a control circuit (not shown) of the illuminating device 502 via a line 509 of a flexible substrate, for example. The control circuit controls the illuminance of the illuminating device 502 in accordance with the illuminance signal. As a result, a liquid crystal display device where the brightness of the display screen is automatically regulated in accordance with the brightness of the environment is provided. Thus, the photosensor 132 of the present invention (the thin film diode 130, the light-blocking layer 160 and the metal oxide layer 180) may be disposed in the frame-shaped area of the TFT array substrate 510 and be used as an ambient sensor that measures the brightness of the environment. Since the thin film diode 130 constituting the photosensor 132 according to an embodiment of the present invention has excellent light detection sensitivity, it provides a liquid crystal display device where the brightness of the display screen is optimized in accordance with the brightness of the environment. Further, a larger thin film diode 130 can be provided than in an implementation where a thin film diode 130 is formed inside the pixel region. Thus, the light receiving area can be increased to further improve light detection sensitivity in a simple manner.

Embodiment 2 has illustrated an implementation where the semiconductor device of the present invention illustrated in Embodiment 1 is used in a liquid crystal panel; however, the semiconductor device of the present invention is not limited to such an application. The semiconductor device of the invention may be used as a display element, such as an EL panel, a plasma panel or the like. Alternatively, the semiconductor device of the invention may be used in various equipment including light detection functionality other than a display element.

While the present invention is not limited to any particular application field, it may be used widely in various equipment in which a photosensor with improved light detection sensitivity is required. Particularly, it may be suitably used in various display elements as a touch sensor or an ambient sensor that measures the brightness of the environment.

1. A photosensor comprising:
a substrate;
a thin film diode provided close to one side of the substrate and having a first semiconductor layer including, at least, an n-type region and a p-type region; and
a light-blocking layer provided between the substrate and the first semiconductor layer, wherein a metal oxide layer is formed on a side of the light-blocking layer facing the first semiconductor layer;
asperities are formed on a side of the metal oxide layer facing the first semiconductor layer; and
the first semiconductor layer has a geometry of asperities conforming with the asperities of the metal oxide layer.

2. The photosensor according to claim 1, wherein the first semiconductor layer has a thickness smaller than a difference in height between an apex and a bottom of the asperities formed on a side of the first semiconductor layer facing the metal oxide layer.

3. The photosensor according to claim 1, wherein a difference in height between an apex and a bottom of the asperities formed on the side of the metal oxide layer facing the first semiconductor layer is in a range of 50 to 100 nanometers.

4. The photosensor according to claim 1, wherein the asperities are formed on an entire surface of the side of the metal oxide layer facing the first semiconductor layer.

5. The photosensor according to claim 1, further comprising:
an interlayer insulating film covering the first semiconductor layer and a pair of electrodes penetrating the interlayer insulating film and electrically connected with the n-type region and the p-type region,
wherein at least one of the electrodes reaches the metal oxide layer.

6. A semiconductor device comprising:
the photosensor according to claim 1; and
a thin film transistor provided close to the same side of the substrate as the thin film diode,
wherein the thin film transistor includes: a second semiconductor layer including a channel region, a source region and a drain region; a gate electrode that controls a conductivity of the channel region; and a gate insulating film provided between the second semiconductor layer and the gate electrode.

7. The semiconductor device according to claim 6, wherein the first semiconductor layer and the second semiconductor layer are formed on a single insulating layer.

8. The semiconductor device according to claim 6, wherein a side of the second semiconductor layer facing the substrate is flat.

9. The semiconductor device according to claim 6, wherein the first semiconductor layer has a thickness that is identical with that of the second semiconductor layer.

10. A liquid crystal panel comprising: the semiconductor device according to claim 6; a counter substrate facing the side of the substrate where the thin film diode and the thin film transistor are provided; and a liquid crystal layer enclosed between the substrate and the counter substrate.
